(19) United States
(12) Patent Application Publication
(10) Pub. No.: US 2007/0287227 A1
(43) Pub. Date: Dec. 13, 2007

(54) Stacked Chips with Underpinning

(76) Inventors: Wyatt Allen Huddleston, Allen, TX (US); Shawn M. O'Connor, McKinney, TX (US)

Correspondence Address: TEXAS INSTRUMENTS INCORPORATED, P O BOX 655474, M/S 3999, DALLAS, TX, 75265, US

(21) Appl. No.: 11/423,029

(22) Filed: Jun. 8, 2006

(51) Int. Cl. H01L 21/00

(52) U.S. Cl. 438/109

(57) ABSTRACT

Methods for assembling multi-chip semiconductor packages, and the resulting assemblies themselves, are disclosed. According to the preferred embodiments of the invention, a first semiconductor chip is affixed to a package substrate and a second semiconductor chip is affixed to at least a portion of a surface of the first semiconductor chip, forming an overhang. Underpinning is interposed for supporting the overhang in resistance to deflection during assembly.

### TECHNICAL FIELD

The invention relates to electronic semiconductor devices and manufacturing. More particularly, the invention relates to microelectronic semiconductor assemblies having two or more vertically stacked chips contained in a single package and to methods related to their manufacture.

### BACKGROUND OF THE INVENTION

Semiconductor device assemblies are subject to many competing design goals. It is very often desirable to minimize the size of electronic apparatus. At the same time, the demand for increased features results in an increase in the number of components on a given device. Efforts are continuously made to design and manufacture devices with reduced area, but attempts to increase density while reducing area will eventually reach a practical limit. As designers attempt to maximize the use of chip area, vertical stacking of components becomes increasingly attractive.

Packaged semiconductor device assemblies containing two or more stacked semiconductor chips typically include a first chip that is attached to a package substrate. Bond pads are disposed around some or all of the periphery of the first chip. Bond wires electrically connect the bond pads of the first chip to corresponding bond pads located on the package substrate. A second chip is affixed to the exposed surface of the first chip, sometimes using a spacer between the first and second chips. Bond pads similarly disposed on the top surface of the second chip are then electrically connected to bond pads on the package substrate, and/or on the first chip, using bond wires. One or more additional chips may also in turn be stacked in a similar manner to form a multi-layer, multi-chip package containing two, three or more stacked chips operably coupled to one another and/or to the package substrate, possibly for external connection elsewhere. Encapsulant is applied to cover the stacked semiconductor chips, the wire bonds, and at least a portion of the package substrate. Variations in stacking methods and structures exist in terms of materials and process steps, but the overall scheme described above is representative of the general state of the art and provides a context for the description of the invention.

In stacked chip assemblies, it is often desirable to use thin chips, or at least to avoid the use of unnecessarily thick chips, in order to reduce the overall height of the final package. In some cases, chips stacked in a package may be of different sizes or shapes. Stacking chips of different geometries sometimes results in one or more “overhangs” wherein a portion of a chip extends unsupported beyond an underlying layer of the stack. One problem that can result in such an arrangement, particularly with the use of thinner chips, is that the overhang portion is susceptible to being deflected during the manufacturing process. Particularly in the case of wirebonding on an overhang, force applied by the wirebonding equipment can cause the overhang to deflect and crack, resulting in the loss of the assembly, reduced yields, and increased costs.

Due to these and other technical challenges, improved methods for manufacturing packaged semiconductor device assemblies containing stacked chips with increased resistance to flexing would be useful and advantageous in the arts. The present invention is directed to overcoming, or at least reducing the effects of, one or more of the problems described above.

### SUMMARY OF THE INVENTION

In carrying out the principles of the present invention, in accordance with preferred embodiments thereof, the invention provides stacked-chip assemblies and methods for their manufacture using underpinning to support chip overhangs against deflection during assembly processes.

According to one aspect of the invention, methods for assembling multi-chip semiconductor packages include steps for affixing a first semiconductor chip to a package substrate and affixing a second semiconductor chip to at least a portion of a surface of the first semiconductor chip, thereby forming an overhang. In a further step, underpinning is interposed for supporting the overhang. Subsequently, wirebonds are made on the overhang.

According to another aspect of the invention, the step of interposing underpinning for supporting an overhang includes placing one or more a pieces of rigid underpinning material in the appropriate location(s).

According to yet another aspect of the invention, the step of interposing underpinning for supporting an overhang includes forming the underpinning of a non-rigid material and at least partially curing the underpinning material prior to the step of affixing a second semiconductor chip to at least a portion of a surface of the first semiconductor chip.

According to still another aspect of the invention, a multi-chip semiconductor device package embodying the invention includes a package substrate supporting a stack of at least two chips. At least part of a chip overlaps a supporting layer, forming an overhang. Underpinning supports the overhang in resistance to deflection.

According to yet another additional aspect of the invention, a multi-chip semiconductor device assembly of the invention employs underpinning material selected for its thermal properties.

The invention has advantages including but not limited to one or more of the following: providing manufacturing methods for packaged stacked-chip assemblies with increased resistance to deflection; providing cost-effective manufacturing methods for robust stacked-chip assemblies; decreasing yield loss during assembly of stacked-chip packages. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top perspective view illustrating an example of a stacked-chip assembly according to a preferred embodiment of the invention;

FIG. 2 is a cut-away side view illustrating another example of a stacked-chip assembly according to an alternative embodiment of the invention;

FIG. 3 is a cut-away side view illustrating an additional example of a stacked-chip assembly according to yet another alternative embodiment of the invention; and

FIG. 4 is a simplified process flow diagram illustrating steps according to preferred methods of the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

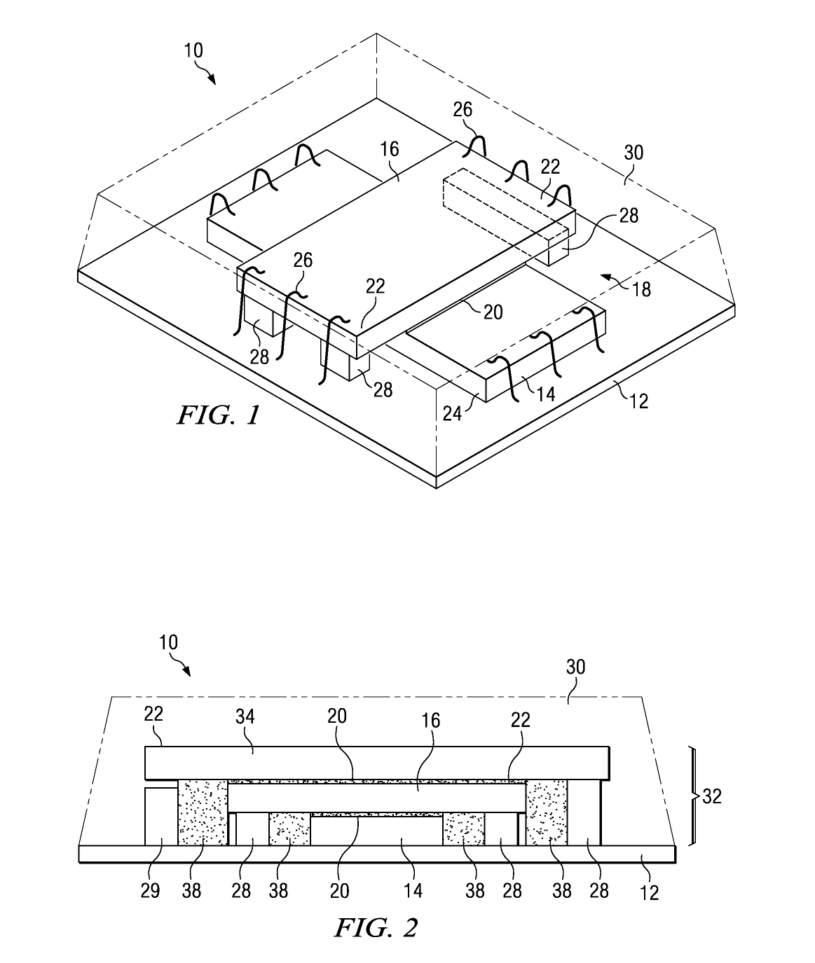

The invention provides stacked-chip assemblies and methods for their manufacture using underpinning to support overhangs within the assembly. The manufacturing steps are sequenced and the components are arranged in such a way that deflection of the chip overhang is minimized or avoided. Preferred embodiments include the use of the invention for wirebonding on overhangs. Referring primarily to FIG. 1, a preferred embodiment of a stacked chip assembly 10 according to the invention and steps used in its manufacture are described. A package substrate 12, in many cases preferably a BGA substrate, is configured to accept a semiconductor chip as common in the arts. A first semiconductor chip 14 is preferably affixed to the package substrate 12. A second semiconductor chip 16 is affixed to at least a portion of a surface of the first semiconductor chip 14, forming a stack 18, in this example consisting of the first and second semiconductor chips 14, 16. Those skilled in the arts will appreciate that an adhesive paste or film 20 may be used, sometimes also with a spacer, between the chips 14,16 of the stack 18. The particulars of the stack 18, and of the remainder of the package 10 itself, may be varied somewhat without departure from the invention as long as an overhang 22 is formed. For example, the first chip 14 shown may be replaced by a flip-chip without departure from the invention. An overhang is formed where one chip extends beyond one or more edges of an underlying layer of the stack. In this case, two overhangs 22 are formed where the second chip 16 extends beyond two of the edges 24, the first chip 14. Of course, there are many possible variations within the scope of the invention. It may be seen in FIG. 1 that the overhangs 22 in this example include portions of the second chip 16 having wirebonds 26. Underpinning 28 for supporting the overhangs 22, is preferably positioned prior to wirebonding in order to prevent or reduce deflection during wirebonding. The underpinning 28 is interposed between the overhang 22 and the package substrate 12 in this example. It should be noted that the underpinning 28 is placed for supporting the overhang 22, and that although in many cases placement between a chip, e.g. 16, and the substrate, e.g. 12, is required, in some instances placement may be between two chips or other structures. As shown in the example of FIG. 1, the underpinning 28 may take the form of one continuous piece supporting an overhang 22, as in the right side of the drawing, or may take the form of two or more pieces of underpinning material 28 deployed at intervals to support the overhang 22, as in the left side of the drawing. As in a further example presented herein, in a stack containing more than two chips, the need for underpinning between chips sometimes also arises and can be met within the scope of the invention.

Preferably the underpinning material 28 and surrounding material, e.g. the IC 16, have similar thermal properties in order to reduce temperature induced stress among the components of the assembly 10. Preferably, the underpinning has a Coefficient of Thermal Expansion (CTE) as close as reasonably practical to the CTE of the surrounding package components, e.g. IC(s), substrate, encapsulant. Since the underpinning material 28 is preferably selected for its thermal and mechanical, and not electrical, properties, a variety of materials may be used, such as e.g., semiconductor, substrate, chips (dummy or live), plastic, epoxy, or ceramic. In the preferred embodiment shown and described above, the underpinning material 28 may be a prepared segment of substrate material or other solid body suitably rigid for placement in position in a manner similar to chip placement. Alternatively, the underpinning material 28 may be formed in place, for example using encapsulant, preferably the same type of encapsulant material 30 ultimately used to encase the assembly 10. Preferably, when forming underpinning of a non-rigid material, the underpinning material is at least partially cured prior to affixing the overhanging semiconductor chip, e.g., the second chip 16 in this example, in place.

The possible variations within the scope of the invention are numerous and cannot all be shown. An example of an alternative embodiment is depicted in FIG. 2, wherein a stack 32 contains a first chip 14 and a second chip 16 as previously described, as well as an additional third chip 34. It can be seen from this example that multiple successive overhangs 22 are possible and that different sizes and shapes of underpinning 28 may be used to support the overhangs 22 and prevent or reduce deflection. As can be seen in FIG. 2, the underpinning indicated at reference numeral 29 need not necessarily be attached to, or even come into contact with, the overhang 22 when in a “rest”, i.e., un-deflected state, so long as the underpinning 29 is located to support the overhang 22 to prevent damaging deflection during wirebonding. In other respects, the package 10 is similar to that of FIG. 1. Although subject to practical limits, in principle, innumerable chips may be stacked and underpinned in a single assembly using the invention.

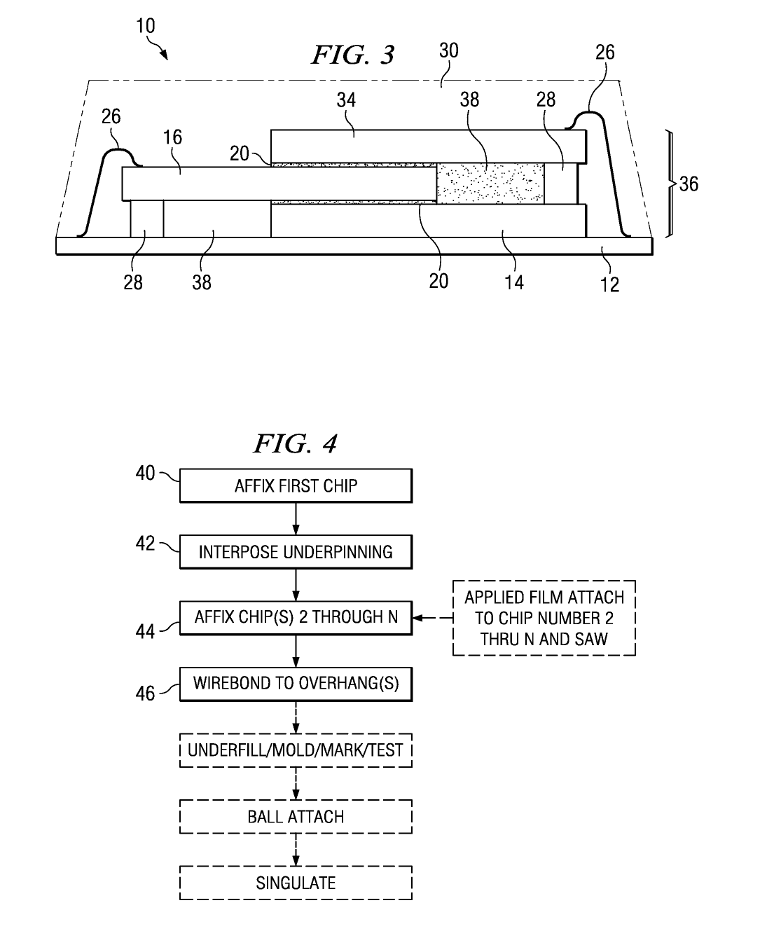

Another example of a preferred embodiment of the invention is shown in FIG. 3, in which underpinning is shown between a chip 16 and substrate 12, as previously described, and also between two successive chips 16, 34 in a stack 36. It should be noted that in any implementation, underfill 38 or encapsulant 30 may also be used to eliminate gaps between or among components of the assembly 10 as generally practiced in the arts.

An alternative view of the steps of preferred methods of the invention is shown in the simplified process flow diagram of FIG. 4. Within the broader context of stacked semiconductor device assembly and packaging, a first chip is affixed to a package substrate, preferably a BGA substrate, as indicated at step 40. Underpinning is provided, step 42, in order to support at least an overhang portion of a second chip affixed to the first chip to form a stack, step 44. As shown at box 46, wirebonding may be performed on the overhang after placement of the underpinning to prevent or reduce deflection of the overhang by the forces applied during wirebonding processes. Of course, additional wirebonding may occur elsewhere on the stack, for example on the first chip, either prior to or subsequent to the placement of the underpinning. Additionally, common manufacturing steps including but not limited to grinding, sawing, underfilling, molding, marking, testing, cleaning, film attachment, ball attachment, and singulation may be performed as generally known in the arts in various combinations without significantly impacting the practice of the invention.

The methods and apparatus of the invention provide one or more advantages including but not limited to reducing damage to semiconductor devices during manufacturing. While the invention has been described with reference to certain illustrative embodiments, those described herein are not intended to be construed in a limiting sense. For example, variations or combinations of steps in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A method for assembling a multi-chip semiconductor package comprising the steps of:
affixing a first semiconductor chip to a package substrate;
affixing a second semiconductor chip to at least a portion of a surface of the first semiconductor chip, thereby forming an overhang;
interposing underpinning for supporting the overhang; and
subsequently coupling a plurality of bond wires to the overhang.

2. A method according to claim 1 wherein the step of interposing underpinning for supporting the overhang further comprises the step of placing underpinning between the overhang and the package substrate.

3. A method according to claim 1 wherein the step of interposing underpinning for supporting the overhang further comprises the step of placing underpinning between the overhang and a chip.

4. A method according to claim 1 wherein the step of interposing underpinning for supporting the overhang further comprises the step of placing one or more pieces of rigid underpinning material.

5. A method according to claim 1 wherein the step of interposing underpinning for supporting the overhang further comprises the step of forming the underpinning of non-rigid material and at least partially curing the underpinning material prior to the step of affixing a second semiconductor chip to at least a portion of a surface of the first semiconductor chip.

6. A method according to claim 1 wherein the step of interposing underpinning for supporting the overhang further comprises, forming the underpinning of encapsulant and at least partially curing the encapsulant.

7. A multi-chip semiconductor device package comprising:
a package substrate;
a multi-layer stack comprising at least two chips and having an overhang wherein at least part of one chip overhangs the edge of an underlying layer of the stack; and
underpinning supporting the overhang for resisting deflection.

8. A multi-chip semiconductor device package according to claim 7 wherein the underpinning and the substrate comprise material having similar thermal properties.

9. A multi-chip semiconductor device package according to claim 7 wherein the underpinning comprises a semiconductor chip.

10. A multi-chip semiconductor device package according to claim 7 wherein the underpinning comprises encapsulant.

11. A multi-chip semiconductor device package according to claim 7 wherein the package substrate comprises a ball grid array package substrate.

12. A multi-chip semiconductor device package according to claim 7 further comprising a plurality of bond wires attached to a chip overhang supported by underpinning.
